(19) United States
(12) Patent Application Publication
(10) Pub. No.: US 2025/0277871 A1
(43) Pub. Date: Sep. 4, 2025

(54) METHODS AND SYSTEMS FOR STATE OF HEALTH (SOH) MONITORING IN FUEL CELLS

(71) Applicant: Robert Bosch GmbH, Stuttgart (DE)

(72) Inventors: Karim GADELRAB, Boston, MA (US); Ulrich BERNER, Stuttgart (DE); Matthias HANAUER, Leonberg (DE); Ulrich SAUTER, Karlsruhe (DE)

(21) Appl. No.: 18/593,092

(22) Filed: Mar. 1, 2024

(51) Int. Cl. G01R 31/40; H01M 8/04537

(52) U.S. Cl. CPC G01R 31/40; H01M 8/04544; H01M 8/04574

(57) ABSTRACT

Disclosed herein are methods and systems for monitoring and estimating the state of health (SOH) of a fuel cell. The state of health of a cell can be estimated through determining the loss of electrochemical active surface area (ECSA) of the cathode catalyst. The method includes providing an external step excitation to a cell, recording the fuel cell response to the external step excitation, and determining an analytical expression of the recorded fuel cell response. Once the analytical expression is determined, at least one parameter of the analytical expression is compared to its beginning of life (BoL) value of that parameter to determine ECSA loss.

### TECHNICAL FIELD

The present disclosure relates to methods and systems for determining the state of health (SOH) of a fuel cell within a vehicle environment. More specifically, the disclosure relates to methods and systems for estimating catalyst electrochemical active surface area losses in a fuel cell.

### BACKGROUND

Accessing the state of health (SOH) of an electrochemical system brings significant value the ease of maintenance and optimization of a vehicle's battery performance. Varying components of a fuel cell contribute to its performance degradation, including the cell's membrane, electrodes, or flow fields. A significant degradation mechanism is the loss of electrochemical active surface area (ECSA) of the cathode's catalyst. ECSA loss can be attributed to catalyst dissolution, surface restructuring, migration and sintering, or catalyst loss of contact with support structure.

Current characterization and diagnostic techniques dedicated to assessing catalyst state of health include cyclic voltammetry (CV), CO-stripping and TEM imaging. These methods' capabilities to measure and track the ECSA differ in accuracy and complexity. They require complicated set-up to acquire and process data and make determinations regarding the change of ECSA. Furthermore, current techniques are not capable of continuous monitoring of the value of ECSA in real time.

In light of current drawbacks, methods and systems are needed which are capable of estimating ECSA loss in catalyst in real time, in a vehicle environment.

### SUMMARY

Described herein are methods and systems for estimating the state of health (SOH) of a fuel cell, which overcome the current drawbacks of existing state of health monitoring methods. The methods disclosed herein are capable of diagnostic determination in real time, and while a vehicle is operating.

In one embodiment, a state of health of a cell can be estimated through determining the loss of electrochemical active surface area (ECSA) of the catalyst. ECSA degradation can occur due to various factors, including, catalyst contamination, catalyst oxidation, membrane support erosion, and other factors.

In one embodiment, a method of estimating the state of health (SOH) of a fuel cell is disclosed. The method comprises providing an external step excitation to a fuel cell, recording the fuel cell response to the external step excitation, and determining an analytical expression of the recorded fuel cell response. Once the analytical fit expression is determined, at least one parameter of the analytical expression is compared to its beginning of life (BoL) value of that parameter.

In an embodiment, the step of providing an external electrical step excitation comprises providing a stepwise pulsed current or voltage. The current or voltage is applied to the cell for several seconds in a step function cycle. Once the external excitation is applied to a cell, a corresponding current or voltage response from the cell is recorded. An analytical expression is derived from the recorded cell response. In one embodiment, the analytical expression representing the cell's response as a function of time is as follows:

R(t)=B+A f(t)

R represents the cell's voltage or current response as a function of time, B represents the constant signal shift (up or down), A is the amplitude of the function f(t), and t is time. Once a value for the amplitude parameter A is determined, the ratio of A at as given time, t, is compared to the value of A at the beginning of life of the cell, i.e. A₍ₜ₎/A_{BoL} is used to estimate the loss of electrochemical active surface area (ECSA) at the given time. A BoL represents the measured value of A at the beginning of life (BoL) of the fuel cell.

At any given time during the cell's life, the parameter A can be determined through the previously described steps, and the value compared to A_{BoL} in order to estimate the degree of ECSA loss. Optionally, if a predetermined threshold limit value is reached in this comparison, then a diagnostic decision can be generated or determined, as to whether maintenance or replacement of the cell or cell stack should be considered.

### Selected Definitions and Nomenclature

As used herein, the term “cell” or “fuel cell” or “FC” are used synonymously and refer to any electrolytic type cell currently known in the art used for energy production and/or storage, including polymer electrolyte membrane fuel cells (PEMC), solid oxide fuel cells (SOFC), alklaline fuel cells (AFC), phosphoric acid fuel cells (PAFC), direct methanol fuel cell (DMFC), molten carbonate fuel cell (MCFC), and so on.

As used herein, the term “external step excitation” refers to the supply of a current or a voltage to a cell or electrolyzer, where the applied current or voltage is applied in a pulsed manner with on and off intervals. The amplitude of each pulse may or may or may not be equal during an application cycle.

The term “about” is used in conjunction with numeric values to include normal variations in measurements as expected by persons skilled in the art, and is understood to have the same meaning as “approximately” and to cover a typical margin of error, such as ±15%, ±10%, ±5%, ±1%, ±0.5%, or even ±0.1% of the stated value. The term “about” also encompasses amounts that differ due to different equilibrium conditions for a composition resulting from a particular initial composition. Whether or not modified by the term “about,” the claims include equivalents to the quantities.

It should be noted that, as used in this specification and the appended claims, the singular forms “a,” “an,” and “the” include plural referents unless the content clearly dictates otherwise. Thus, for example, reference to a composition containing “a compound” includes having two or more compounds that are either the same or different from each other. It should also be noted that the term “or” is generally employed in its sense including “and/or” unless the content clearly dictates otherwise. As used herein, “and/or” refers to and encompasses any and all possible combinations of one or more of the associated listed items, as well as the lack of combinations when interpreted in the alternative (“or”).

In the interest of brevity and conciseness, any ranges of values set forth in this specification contemplate all values within the range and are to be construed as support for claims reciting any sub-ranges having endpoints which are real number values within the specified range in question. By way of a hypothetical illustrative example, a disclosure in this specification of a range of from 1 to 5 shall be considered to support claims to any of the following ranges: 1-5; 1-4; 1-3; 1-2; 2-5; 2-4; 2-3; 3-5; 3-4; and 4-5.

The term “substantially” is utilized herein to represent the inherent degree of uncertainty that can be attributed to any quantitative comparison, value, measurement, or other representation. The term “substantially” is also utilized herein to represent the degree by which a quantitative representation can vary from a stated reference without resulting in a change in the basic function of the subject matter at issue.

The term “comprise,” “comprises,” and “comprising” as used herein, specify the presence of the stated features, integers, steps, operations, elements, and/or components, but do not preclude the presence or addition of one or more other features, integers, steps, operations, elements, components, and/or groups thereof.

As used herein, the transitional phrase “consisting essentially of” means that the scope of a claim is to be interpreted to encompass the specified materials or steps recited in the claim and those that do not materially affect the basic and novel characteristic(s) of the claimed invention. Thus, the term “consisting essentially of” when used in a claim of this invention is not intended to be interpreted to be equivalent to “comprising.”

As used herein, the terms “increase,” “increasing,” “increased,” “enhance,” “enhanced,” “enhancing,” and “enhancement” (and grammatical variations thereof) describe an elevation of at least about 1%, 5%, 10%, 15%, 25%, 50%, 75%, 100%, 150%, 200%, 300%, 400%, 500% or more as compared to a control.

As used herein, the terms “reduce,” “reduced,” “reducing,” “reduction,” “diminish,” and “decrease” (and grammatical variations thereof), describe, for example, a decrease of at least about 1%, 5%, 10%, 15%, 20%, 25%, 35%, 50%, 75%, 80%, 85%, 90%, 95%, 97%, 98%, 99%, or 100% as compared to a control. In particular embodiments, the reduction can result in no or essentially no (i.e., an insignificant amount, e.g., less than about 10% or even 5% or even 1%) detectable activity or amount.

The terms “preferred” and “preferably” refer to embodiments that may afford certain benefits, under certain circumstances. However, other embodiments may also be preferred, under the same or other circumstances. Furthermore, the recitation of one or more preferred embodiments does not imply that other embodiments are not useful, and is not intended to exclude other embodiments from the scope of the present disclosure.

The terms “over,” “under,” “between,” and “on” as used herein refer to a relative position of one component or material with respect to other components or materials where such physical relationships are noteworthy. For example in the context of materials, one material or material disposed over or under another may be directly in contact or may have one or more intervening materials. Moreover, one material disposed between two materials or materials may be directly in contact with the two layers or may have one or more intervening layers. In contrast, a first material or material “on” a second material or material is in direct contact with that second material/material. Similar distinctions are to be made in the context of component assemblies.

As used throughout this description, and in the claims, a list of items joined by the term “at least one of” or “one or more of” can mean any combination of the listed terms. For example, the phrase “at least one of X, Y or Z” can mean X; Y; Z; X and Y; X and Z; Y and Z; or X, Y and Z

### BRIEF DESCRIPTION OF THE DRAWINGS

The principles, features and advantages of the present invention may be better understood by describing the invention in more detail below with reference to the accompanying drawings. The drawings include:

FIG. 1 shows a flowchart diagram of a method for determining the state of health (SOH) of a fuel cell of a vehicle, in accordance with embodiments disclosed herein.

FIG. 2A shows a graph of voltage of current external step excitation, in accordance with embodiments disclosed herein.

FIG. 2B shows a top graph of an analytical expression of a current response while a fuel cell is running on H2/Air environment, and a bottom graph of an analytical expression of a current response while a fuel cell is operating in a H2/N2 environment.

FIG. 3 shows a top graph of a fitting parameter A of an analytical expression, in accordance with embodiments disclosed herein.

### DETAILED DESCRIPTION

Embodiments of the present disclosure are described herein. It is to be understood, however, that the disclosed embodiments are merely examples and other embodiments can take various and alternative forms. The figures are not necessarily to scale; some features could be exaggerated or minimized to show details of particular components. Therefore, specific structural and functional details disclosed herein are not to be interpreted as limiting, but merely as a representative basis for teaching one skilled in the art to variously employ the embodiments. As those of ordinary skill in the art will understand, various features illustrated and described with reference to any one of the figures can be combined with features illustrated in one or more other figures to produce embodiments that are not explicitly illustrated or described. The combinations of features illustrated provide representative embodiments for typical applications. Various combinations and modifications of the features consistent with the teachings of this disclosure, however, could be desired for particular applications or implementations.

Described herein are methods and systems for estimating the state of health (SOH) of a cell, and in particular a polymer electrolyte membrane (PEM) fuel cell or an electrolyzer. In one embodiment, a state of health of a cell can be estimated through determining the loss of electrochemical active surface area (ECSA) of the catalyst. ECSA degradation can occur due to various factors, including, catalyst contamination, catalyst oxidation, membrane support erosion, and other factors.

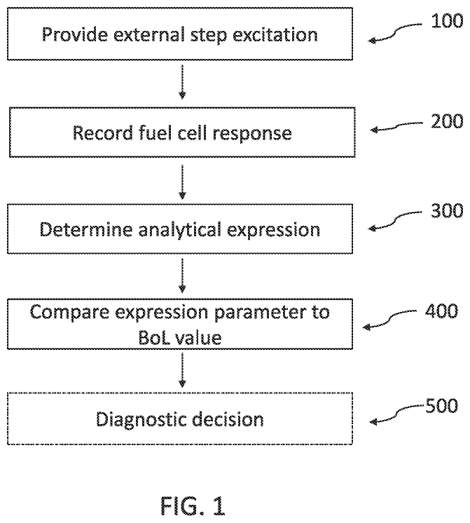

In one embodiment, a method of estimating the state of health (SOH) of a fuel cell is shown in the flowchart of FIG. 1. The method includes providing an external step excitation to a fuel cell 100, recording the fuel cell response to the external step excitation 200, and determining an analytical expression of the recorded fuel cell response 300. Once the analytical fit expression is determined, at least one parameter of the analytical expression is compared to its beginning of life (BoL) value of that parameter 400.

In an embodiment, the step of providing an external electrical step excitation 100 comprises providing a stepwise pulsed current or stepwise pulsed voltage. The current or voltage is applied to the cell for several seconds in a step function cycle, meaning that the current or voltage is applied in a pulsed manner with on/off repeating periods. In one embodiment the current or voltage applied to a cell can lasts 1-10 seconds, or 1-8 seconds, or 1-6 seconds, or 1-4 seconds, or 1-2 seconds, for each on period, having the same amplitude each time. The off periods of the pulse, can be equal in duration to the on periods, or in certain embodiments differ from the duration of the on period of the applied current or voltage. The entire cycle of on/off repeated pulses may last 30 seconds to 1 minute per cycle. In one embodiment, an applied current is applied in an electric current density of about 1.5 to 3 A/cm². In other embodiments, where voltage is applied as the external electrical step excitation, the applied voltage is about 0.8 to 1.0 Volts.

In an embodiment, the external step excitation is applied to each cell in a fuel cell stack, or to a segment of the stack containing more than one cell. Determining the state of health at each individual cell or at a stack segment, allows the diagnostic decision to be made on a single cell or segment level, so that the problematic cells can be maintained or replaced, instead of the entire cell stack. In one embodiment, a diagnostic decision is determined or generated if loss of electrochemical active surface area reaches a preset limit value.

Once the external excitation is applied to a cell, a corresponding current or voltage response from the cell is recorded. An analytical expression is derived from the recorded cell response. In one embodiment, the analytical expression representing the cell's response as a function of time is as follows:

R(t)=B+A f(t)

R represents the cell's voltage or current response as a function of time, B represents the direct current (DC) shift (up or down), A is the amplitude of the function f(t), and t is time. Once a value for the amplitude parameter A is determined, the ratio of A at as given time, t, is compared to the value of A at the beginning of life of the cell, i.e. A₍ₜ₎/A_{BoL} is used to estimate the loss of electrochemical active surface area (ECSA) at the given time. A_{BoL} represents the measured value of A at the beginning of life (BoL) of the fuel cell, which can be determined by conducting the aforementioned protocol or steps in a factory setting when the cell is first tested, for example prior to vehicle installation. This way, reference parameters can be recorded for A_{BoL} and logged into a specific vehicle's battery management system.

At any given time during the cell's life, the parameter A can be determined through the previously described steps, and the value compared to A_{BoL} in order to estimate the degree of ECSA loss. Optionally, if a predetermined threshold limit value is reached in this comparison, then a diagnostic decision can be determined by the battery management system, as to whether maintenance or replacement of the cell or cell stack should be considered.

The function f(t) will depend and vary based on the cause of the catalyst degradation, such as catalyst contamination, catalyst oxidation, membrane support erosion, or a combination of these and other factors. In one embodiment the function f(t) may be equal to an inverse power law of time. In certain embodiments the function f(t) is equal to tⁿ where n is a real number, In other embodiments, the function f(t) is equal to a logarithmic or an exponential function of time. In other embodiments, the function f(t) is equal to t⁽⁻ⁿ⁾ where, n ranges from −0.5 to −3.0.

The method steps described herein can be carried out while the cell is in idle mode or during operation. In other words, the particular cell can have either air (or O₂) supplied at the cathode, or it can be in oxygen depletion mode and N₂ is supplied at the cathode side, while H₂ is supplied at the anode side. An auxiliary N₂ source can be coupled to the cell in order to supply N2, for testing in idle mode.

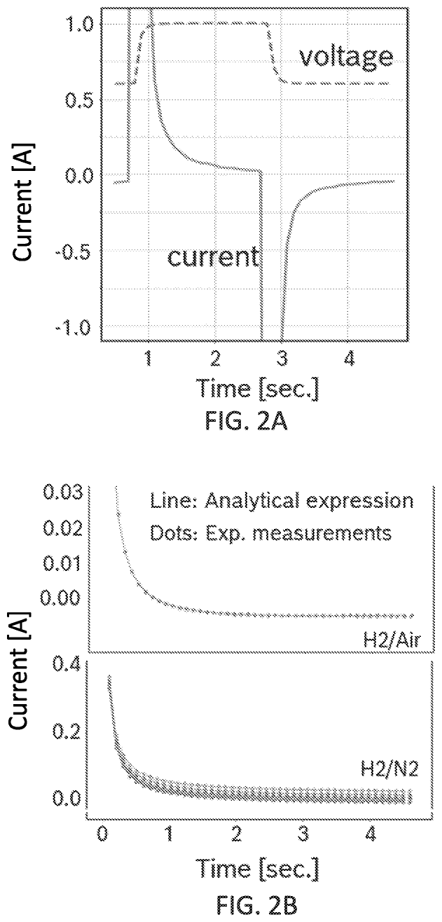

Shown in FIG. 2A and 2B is a comparison of a cell's current response, after a stepped voltage excitation has been applied. The recorded experimental current is logged either in H₂/N₂ or H₂/Air (change of supplied gas at the cathode of the cell). Analytical fittings that captures the catalyst's current response are shown in FIG. 2B. As can be seen in the results of the current response in FIG. 2B, the analytical expression fits the experimental measurements accurately. The entire current response of a cycle can be utilized to determine parameter (A) that can be referenced to its value at the beginning of life. Having the functional form of the catalyst response at either N₂ or air at the cathode enables ECSA estimation either during the cell's idle state (N₂ at the cathode), or during cell operation (air at the cathode). The applied voltage is supplied for a few seconds (4 seconds as shown in FIG. 2B), which highlights the speed at which this test can be conducted.

In embodiments, a voltage or current controller is connected to each cell in a

stack, so that application of a voltage or current and readings of the voltage or current response can be acquired for each individual cell in a stack.

Also disclosed is a system for monitoring the state of health of a fuel cell or fuel cell stack. In one embodiment, the system includes at least one external excitation source connected to at least one fuel cell. The system further includes a gas control unit configured to control the supply of reactant or purge gas to a cathode of the fuel cell, and a diagnostic unit configured to perform diagnostic analysis based on a recorded current or voltage response from the fuel cell.

In one embodiment, the at least one external excitation source comprises a voltage or current controller which is configured to provide the external step excitation and record the fuel cell response to that excitation. The at least one electrical excitation source supplies a step wise pulsed current or pulsed voltage to the fuel cell, while the fuel cell is in idle mode or during operation mode. In certain embodiments, an external excitation source is connected to each cell is a stack.

The gas control unit is utilized to for gas supply at the cathode of each cell. In certain embodiments, O₂ or air is supplied to the cathode, under normal cell operations. In other embodiments, N₂ purge gas is supplied at the cathode, during idle conditions for that cell. Therefore, the gas control unit comprises a nitrogen gas supply source, which can be routed to the cathode side of a cell, in cases where the cell will be tested in idle mode.

In one embodiment, the diagnostic unit receives data comprising the recorded current or voltage response from the fuel cell, after the excitation step. The diagnostic unit generates parameters from the received data, which are compared to beginning of life parameters for the fuel cell. The beginning of life parameters are generated and stored in the diagnostic unit, for comparison and determination of a diagnostic decision based on the estimated ECSA loss. The diagnostic unit can be a stand-alone unit, or it may be incorporated in a vehicle's electronic control unit. The diagnostic unit may generate a diagnostic decision based on the determined ECSA loss, with regards to whether the cell or cell stack needs maintenance, repair or replacement.

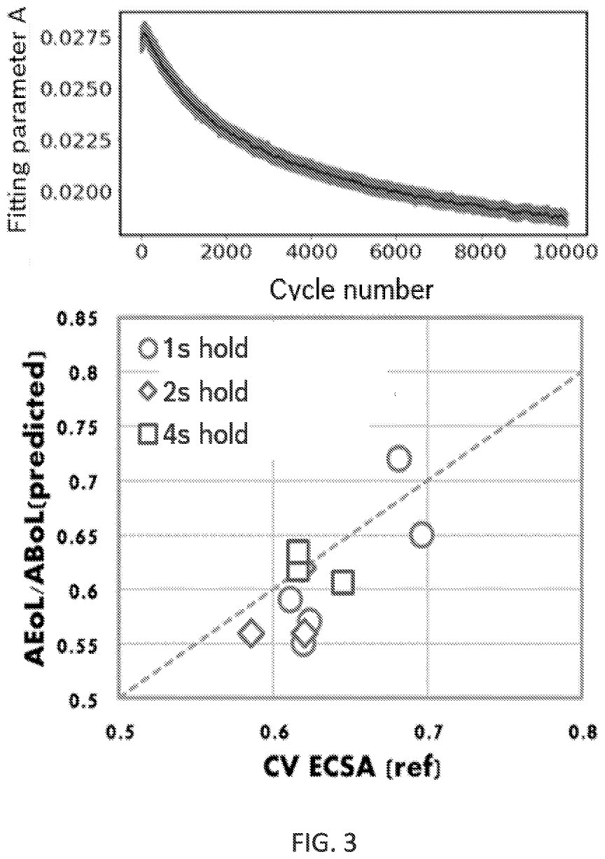

Shown in FIG. 3 is a plot of continuous monitoring of the fitting parameter (A) as a function of cycle number. Cycling the voltage pulse 10,000 times, fitting parameter (A) shows a continuous decay. The ratio of the end of life parameter A (EOL) to beginning of life (BOL), A_{EoL}/A_{BoL} correlates accurately with ECSA loss measured by standard Cyclic Voltammetry (CV). Hence, this demonstrates that the change of fitting parameter (A) of the determined analytical expression serves as an accurate determination measure of ECSA loss and can be used as a diagnostic tool, in real time, in a vehicle environment. Additionally shown in FIG. 3 is a comparison of the duration of the pulsed voltage. A 1 second, 2 seconds and 4 seconds hold is shown and compared. The results of this testing show that voltage or current hold time is not a factor that impacts ECSA loss determination. The inventors have thus discovered that short pulses can be used in the proposed SOH estimation methods, making these diagnostic method and systems more efficient than currently existing methods in the prior art.

While exemplary embodiments are described above, it is not intended that these embodiments describe all possible forms encompassed by the claims. The words used in the specification are words of description rather than limitation, and it is understood that various changes can be made without departing from the spirit and scope of the disclosure. As previously described, the features of various embodiments can be combined to form further embodiments of the invention that may not be explicitly described or illustrated. While various embodiments could have been described as providing advantages or being preferred over other embodiments or prior art implementations with respect to one or more desired characteristics, those of ordinary skill in the art recognize that one or more features or characteristics can be compromised to achieve desired overall system attributes, which depend on the specific application and implementation. These attributes can include, but are not limited to cost, strength, durability, life cycle cost, marketability, appearance, packaging, size, serviceability, weight, manufacturability, ease of assembly, etc. As such, to the extent any embodiments are described as less desirable than other embodiments or prior art implementations with respect to one or more characteristics, these embodiments are not outside the scope of the disclosure and can be desirable for particular applications.

What is claimed is:

1. A method of monitoring the state-of-health of a fuel cell, the method comprising:
providing an external step excitation to a fuel cell;
recording the fuel cell response to the external step excitation;
determining an analytical expression of the recorded response;
determining loss of electrochemical active surface area by comparing at least one parameter of the analytical expression to a beginning of life (BoL) value of said parameter.

2. The method of claim 1, wherein providing an external step excitation comprises providing a step excitation of current or voltage.

3. The method of claim 1 wherein recording the fuel cell response comprising recording a current response or a voltage response.

4. The method of claim 1, wherein the analytical expression of the recorded response is R(t)=B+A f(t), wherein B represents constant signal shift, A is amplitude of the function, and t is time.

5. The method of claim 1, wherein the loss of electrochemical active surface area is determined by comparing Aₜ/A_{BoL}.

6. The method of claim 1, wherein H₂ is supplied at an anode of the fuel cell and air or O₂ is supplied to a cathode of the fuel cell.

7. The method of claim 1, wherein H₂ is supplied at an anode of the fuel cell and air or N₂ is supplied to a cathode of the fuel cell.

8. The method of claim 2, wherein the step excitation of current or voltage comprises applying a cycle of pulsed current or voltage, wherein a pulse in the cycle lasts 1-10 seconds.

9. The method of claim 8, wherein the cycle lasts 30 seconds to 60 seconds, and is applied at least once daily.

10. The method of claim 1, further comprising determining a diagnostic decision if loss of electrochemical active surface area reaches a predetermined limit value.

11. The method of claim 1, wherein the external excitation is provided while the fuel cell is idle or during operation.

12. The method of claim 1, wherein a voltage controller is connected to the fuel cell and configured for providing the external step excitation and recording the fuel cell response.

13. A system for monitoring the state-of-health of a fuel cell or fuel cell stack, the system comprising:
at least one electrical excitation source connected to at least one fuel cell;
a gas control unit configured to control the supply of reactant or purge gas to a cathode of the fuel cell;
a diagnostic unit configured to perform diagnostic analysis based on a recorded current or voltage response from the fuel cell.

14. The system of claim 13, wherein the at least one electrical excitation source comprises a voltage or current controller.

15. The system of claim 13, wherein the gas control unit comprises a nitrogen gas supply source.

16. The system of claim 13, wherein the diagnostic unit receives data comprising a current or voltage response from the fuel cell.

17. The system of claim 16, wherein the diagnostic unit generates parameters from the received data, which are compared to beginning of life parameters for the fuel cell.

18. The system of claim 13, wherein the at least one electrical excitation source supplies a pulsed current or voltage to the fuel cell, while the fuel cell is in idle mode or during operation.

19. The system of claim 13, wherein the diagnostic unit is coupled to a vehicle's electronic control unit.

20. A method of monitoring the state-of-health of a fuel cell, the method comprising:
providing an external step excitation to a fuel cell;
recording the fuel cell response to the external step excitation;
determining an analytical expression of the recorded response;
wherein the analytical expression of the recorded response is
R(t)=B+A f(t), wherein B represents constant signal shift, A is amplitude of the function, and t is time; and
determining loss of electrochemical active surface area by comparing at least one parameter of the analytical expression to a beginning of life (BoL) value of said parameter.
